(19) United States
(12) Patent Application Publication
(10) Pub. No.: US 2026/0101756 A1
(43) Pub. Date: Apr. 9, 2026

(54) SEMICONDUCTOR PACKAGE, SEMICONDUCTOR PACKAGE MANUFACTURING METHOD, AND SEMICONDUCTOR PACKAGE MANUFACTURING DEVICE

(71) Applicant: Samsung Electronics Co., Ltd., Suwon-si (KR)

(72) Inventors: Hyeonrae Cho, Suwon-si (KR); Gongmyeong Kim, Suwon-si (KR); Chaein Moon, Suwon-si (KR); Taejae Park, Suwon-si (KR)

(21) Appl. No.: 19/290,655

(22) Filed: Aug. 5, 2025

(30) Foreign Application Priority Data
Oct. 7, 2024 (KR) 10-2024-0135634

(51) Int. Cl. H01L 23/00; H01L 23/31; H01L 25/065

(52) U.S. Cl. CPC H10W 42/121; H10W 74/111; H10W 90/00; H10W 72/07141; H10W 72/072; H10W 72/07202; H10W 72/07231; H10W 72/07232; H10W 72/073; H10W 72/07338; H10W 72/241; H10W 72/283; H10W 74/15; H10W 90/724; H10W 90/734

(57) ABSTRACT

A semiconductor package includes a substrate including a first layer, a plurality of structures extending in a first direction on the first layer by a first length and including the same materials as the first layer, and a first semiconductor chip bonded to the substrate, wherein a separation distance in the first direction between a first surface of the first semiconductor chip facing the substrate and the substrate is determined by the first length.

### CROSS-REFERENCE TO RELATED APPLICATION

This application claims priority to and the benefit of Korean Patent Application No. 10-2024-0135634 filed at the Korean Intellectual Property Office on Oct. 7, 2024, the entire contents of which are incorporated herein by reference.

### BACKGROUND

A semiconductor package is formed by stacking at least one semiconductor chip and a substrate. A semiconductor package may be formed by bonding semiconductor chips to each of the lower and upper portions of a substrate. The substrate may be formed by bonding solder bumps or solder balls to a substrate body, such as a PCB substrate. Semiconductor chips and substrates are bonded together through a reflow process.

The reflow process is a process in which a pad of a semiconductor chip and a solder bump on a substrate are brought into contact, and a certain amount of heat is applied to melt the solder bump and bond it to the pad.

### SUMMARY

For purposes of this disclosure, it has been recognized that a gap between the semiconductor chip and the substrate may not be constant due to warpage of the semiconductor chip during the reflow process. Accordingly, it would be desirable to keep the gap between the semiconductor chip and the substrate constant.

Some aspects of the present disclosure provide semiconductor packages capable of preventing warpage of a semiconductor chip, corresponding semiconductor package manufacturing methods, and corresponding semiconductor package manufacturing devices.

Some aspects of the present disclosure provide semiconductor packages capable of maintaining a constant gap between a semiconductor chip and a substrate and preventing non-wet defects, corresponding semiconductor package manufacturing methods, and corresponding semiconductor package manufacturing devices.

A semiconductor package according to some implementations includes a substrate including a first layer, a plurality of structures, wherein the plurality of structures protrude from the first layer in a first direction by a first length and include a same material as the first layer, and a first semiconductor chip bonded to the substrate, wherein (i) a first surface of the first semiconductor chip and (ii) the substrate are separated from one another in the first direction by a separation distance, the separation distance is determined based on the first length.

A semiconductor package manufacturing method according to some implementations includes forming a structure that protrudes from a substrate in a first direction, heating a solder that electrically connects a semiconductor chip and the substrate, wherein the semiconductor chip is spaced apart from the substrate in the first direction, and applying a pressure to the semiconductor chip in a direction opposite to the first direction, wherein a first surface of the semiconductor chip contacts the structure, wherein the structure includes a solder resist, and wherein the first surface faces the substrate.

A semiconductor package manufacturing device according to some implementations includes a first jig disposed on a stage and in contact with a first surface of a substrate, a second jig in contact with a second surface of the substrate, wherein the second surface is opposite to the first surface, a heater configured to heat a solder that electrically connects the substrate with a semiconductor chip bonded to the substrate, wherein the substrate and the semiconductor chip are spaced apart in a first direction, and a compressor configured to pressurize a fourth surface of the semiconductor chip, wherein the fourth surface is opposite to a third surface of the semiconductor chip, and wherein the third surface faces the substrate, wherein a length of the second jig in the first direction is equal to a sum of a gap between the substrate and the semiconductor chip in the first direction and a thickness of the semiconductor chip in the first direction.

### BRIEF DESCRIPTION OF THE DRAWINGS

FIG. 1 schematically illustrates an example of a semiconductor package manufacturing device.

FIGS. 2 to 6 are cross-sectional views of intermediate stages in the formation of an example of a semiconductor package.

FIG. 7A is a cross-sectional view of an intermediate stage in the formation of an example of a semiconductor package.

FIG. 7B is a top view of a semiconductor package along, or from the perspective indicated by, line A-A′ of FIG. 7A.

FIG. 8 is a cross-sectional view of an intermediate stage in the formation of an example of a semiconductor package.

FIG. 9 schematically illustrates an example of a semiconductor package manufacturing device.

FIGS. 10 to 13 are cross-sectional views of intermediate stages in the formation of an example of a semiconductor package.

FIG. 14 schematically illustrates an example of a semiconductor package manufacturing device.

FIGS. 15 to 17 are flow charts illustrating examples of semiconductor package manufacturing methods.

### DETAILED DESCRIPTION

In the subsequent description, the same reference numerals are used to indicate the same or similar elements, and duplicate or substantially similar descriptions are omitted.

In the subsequent description, the dimensions of the components are not limited to the disclosed ranges or values and may vary depending on process conditions and/or desired device properties. Additionally, the formation or arrangement of a first structure on or above a second structure in the following description may include implementations in which the first and second structures are formed in direct contact, and may also include implementations in which additional structures may be formed between the first and second structures so that the first and second structures do not directly contact each other. For simplicity and clarity, the various structures may be drawn arbitrarily at different scales.

Spatially relative terms, such as “beneath,” “below,” “lower,” “above,” “upper” and the like, may be used herein for ease of description to describe one element or feature's relationship to another element(s) or feature(s) as illustrated in the drawings.

In the flowcharts provided in the drawings, the operation order may be changed, several operations may be merged, certain operations may be divided, and specific operations may not be performed, without departing from the scope of this disclosure.

In the description, expressions described in the singular in this specification may be interpreted as singular or plural unless an explicit expression such as “one” or “single” is used. While terms including ordinal numbers, such as “first” and “second,” etc., may be used to describe various components, such components are not limited to the above terms. These terms are only used to distinguish one component from another and do not imply any ordering.

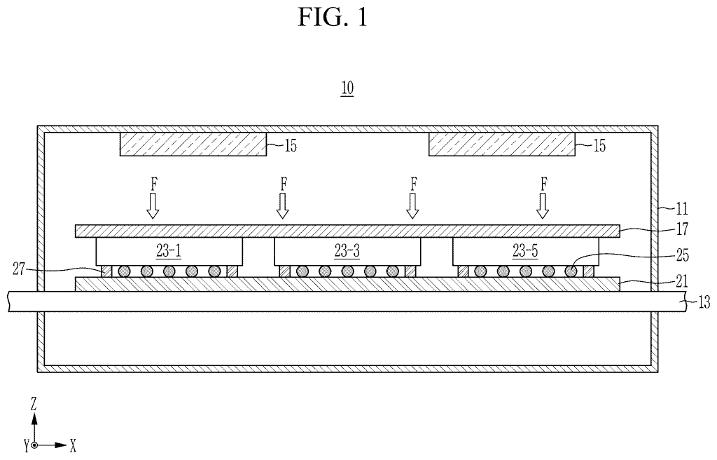

FIG. 1 schematically illustrates an example of a semiconductor package manufacturing device. In some implementations, a manufacturing device 10 may include a process chamber 11 and a stage 13. The process chamber 11 may form an internal space for performing a manufacturing process for a semiconductor package including a substrate 21 and a plurality of semiconductor chips 23-1, 23-3, and 23-5. The stage 13 may support the substrate 21. In some implementations, the stage 13 may include a conveyor belt configured to transport the substrate 21 and the plurality of semiconductor chips 23-1, 23-3, and 23-5 in one direction.

In some implementations, the manufacturing device 10 may be a reflow device configured to perform a reflow process on solder 25 disposed between the substrate 21 and the plurality of semiconductor chips 23-1, 23-3, and 23-5. The manufacturing device 10 may include a heater 15 (e.g., one or more heaters) in the process chamber 11. The heater 15 may include a heat source for heating the solder 25 to a predetermined temperature. For example, the heater 15 may include a heater configured to generate hot air, an infrared heater, or a laser beam. The manufacturing device 10 may include a cooler for cooling the solder 25 melted by the heater 15. For example, the cooler may supply air at room temperature or lower to the solder 25 to cure it. Additionally, the manufacturing device 10 may include a temperature sensor for detecting the temperature inside the process chamber 11 and/or temperature of the solder 25.

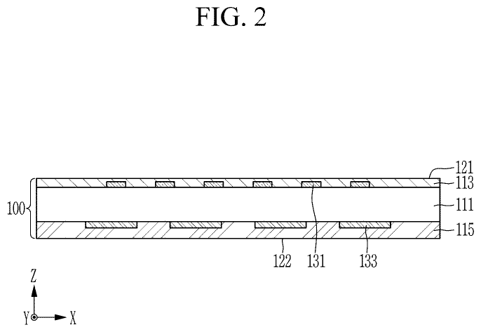

In some implementations, a structure 27 may be disposed between the substrate 21 and the plurality of semiconductor chips 23-1, 23-3, and 23-5. In the manufacturing process of a semiconductor package, the structure 27 disposed on the substrate 21 and below the plurality of semiconductor chips 23-1, 23-3, and 23-5 may be formed. The structure 27 may include, for example, a solder resist. A specific description of the method for forming the structure 27 will be described later with reference to FIGS. 2 to 7.

In some implementations, the manufacturing device 10 may further include a compressor 17. The compressor 17 may apply a plurality of forces F to the plurality of semiconductor chips 23-1, 23-3, and 23-5. For example, when the solder 25 is heated by the heater 15 to a predetermined temperature (e.g., 217° C., which may be the boiling point of the solder 25), the compressor 17 may apply the plurality of forces F to the plurality of semiconductor chips 23-1, 23-3, and 23-5 to prevent or reduce warpage of the plurality of semiconductor chips 23-1, 23-3, and 23-5. At this time, since the structure 27 supports the plurality of semiconductor chips 23-1, 23-3, and 23-5 on the substrate 21, the gap between the plurality of semiconductor chips 23-1, 23-3, and 23-5 and the substrate 21 may be formed to be constant with a predetermined length or height (e.g., constant along the X-direction).

FIGS. 2 to 8 are cross-sectional views of intermediate steps or stages in the formation of a semiconductor package according to some implementations. For convenience of description, only one semiconductor chip (e.g., 23-1) among the plurality of semiconductor chips 23-1, 23-3, and 23-5 (or more) disposed on the stage 13 of FIG. 1 is described.

Referring to FIG. 2, a substrate 100 may have a flat shape or a panel shape. The substrate 100 may include an upper surface 121 and a lower surface 122 opposite the upper surface 121 in a first direction (e.g., the Z direction, which may be a vertical direction). The upper surface 121 and the lower surface 122 may each be flat. The upper surface 121 and the lower surface 122 may be parallel to each other. The substrate 100 may be a printed circuit board (PCB) or an interposer substrate but is not limited thereto.

In some implementations, the substrate 100 may include a base layer 111. The base layer 111 may include at least one material selected from phenol resin, epoxy resin, and polyimide. For example, the base layer 111 may include at least one material selected from polyimide, FR-4 (Flame Retardant 4), tetrafunctional epoxy, polyphenylene ether, epoxy/polyphenylene oxide, bismaleimide triazine (BT), Thermount, cyanate ester, and liquid crystal polymer.

In some implementations, the substrate 100 may include upper connection pads 131 formed on a first surface of the base layer 111 and lower connection pads 133 formed on a second surface opposite the first surface of the base layer 111 in a first direction (Z). The interior of the base layer 111 may include internal wiring that electrically connects the upper connection pads 131 and the lower connection pads 133. The upper connection pads 131 and the lower connection pads 133 may include metals such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), etc., or alloys thereof.

In some implementations, the substrate 100 may include a first passivation layer 113 formed on the first surface of the base layer 111 and a second passivation layer 115 formed on the second surface. The first passivation layer 113 may cover the first surface of the base layer 111 and the upper connection pads 131, and the second passivation layer 115 may cover the second surface of the base layer 111 and the lower connection pads 133. The first passivation layer 113 and the second passivation layer 115 may include, for example, a solder resist. The first passivation layer 113 and the second passivation layer 115 may be provided from a dry film solder resist (DFSR) or a liquid solder resist material.

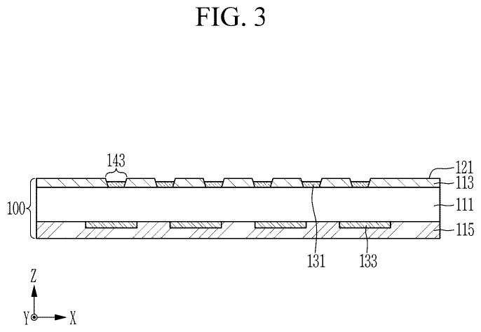

Referring to FIG. 3, in some implementations, an exposure and development process on the first passivation layer 113 may be performed. By performing the exposure and development process on the first passivation layer 113, upper openings 143 may be formed. For example, as a result of performing the exposure process on the first passivation layer 113, the first passivation layer 113 may include an exposed region that has been exposed and an unexposed region that has not been exposed. Then, a development process for the first passivation layer 113 may be performed. As a result of performing the development process on the first passivation layer 113, the exposed region of the first passivation layer 113 may be removed and the upper openings 143 may be formed. The upper connection pads 131 may be exposed by the upper openings 143.

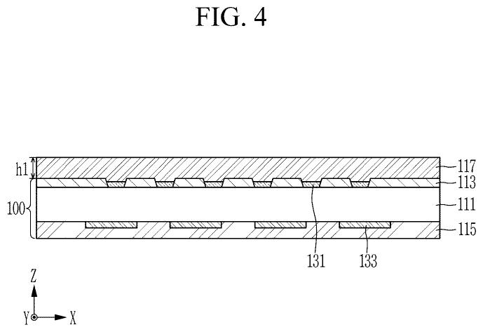

Referring to FIG. 4, in some implementations, a second material layer 117 may be formed on the first passivation layer 113. The second material layer 117 may include, for example, a solder resist. The second material layer 117 may cover the upper surface 121 of the substrate 100. The second material layer 117 may be provided from the DFSR or a liquid solder resist material. In some implementations, the second material layer 117 may extend in the first direction (Z) on the first passivation layer 113 and the upper connection pads 131 within the upper openings 143. For example, the second material layer 117 may extend from, or protrude from, the first passivation layer 113 in the first direction (Z) by a first length h1. Here, the first length h1 may be a predetermined length. According to some implementations, the separation distance between the substrate 100 and a semiconductor chip (23 in FIG. 1) may be determined by the first length h1 of the second material layer 117.

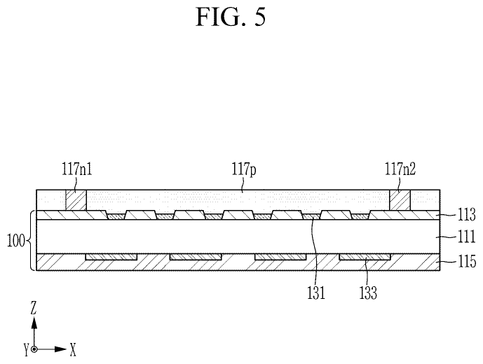

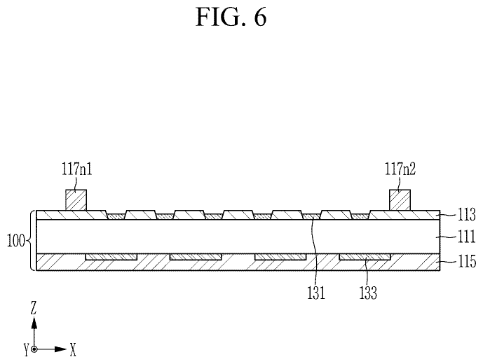

Referring to FIG. 5, in some implementations, an exposure process may be performed on the second material layer 117. As a result of performing the exposure process on the second material layer 117, the second material layer 117 may include an exposed region 117p that has been exposed and unexposed regions 117n1 and 117n2 that have not been exposed. Then, a development process on the second material layer 117 may be performed. Referring to FIG. 6, as a result of performing the development process on the second material layer 117, the exposed region 117p of the second material layer 117 may be removed, and the unexposed regions 117n1 and 117n2 may remain. Hereinafter, the unexposed regions may be referred to as first structures 117n1 and 117n2.

In some implementations, the first structures 117n1 and 117n2 may extend in a second direction (Y) on the first passivation layer 113. Although the first structures 117n1 and 117n2 are shown here as extending in the second direction (Y), the extension is not limited thereto. For example, the first structures 117n1 and 117n2 may extend in the first direction (X) on the first passivation layer 113, or the first structures 117n1 and 117n2 may extend in the first direction (X) and the second direction (Y) on the first passivation layer 113, thereby having, for example, a square-ring shape.

In some implementations, the first structures 117n1 and 117n2 may include an insulating material. For example, the first structures 117n1 and 117n2 may include solder resist, epoxy resin, and/or polyimide. In some implementations, the first structures 117n1 and 117n2 may be formed of the same material as the first passivation layer 113 of the substrate 100. For example, the lower portion of the first structures 117n1 and 117n2 may be in contact with the first passivation layer 113 and may be formed of the same material (e.g., solder resist) as the first passivation layer 113.

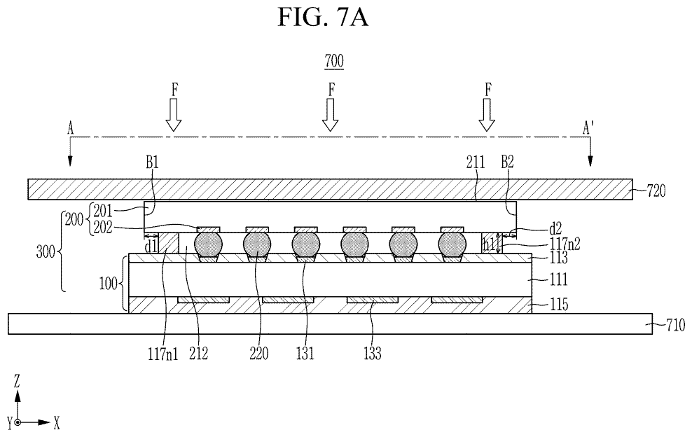

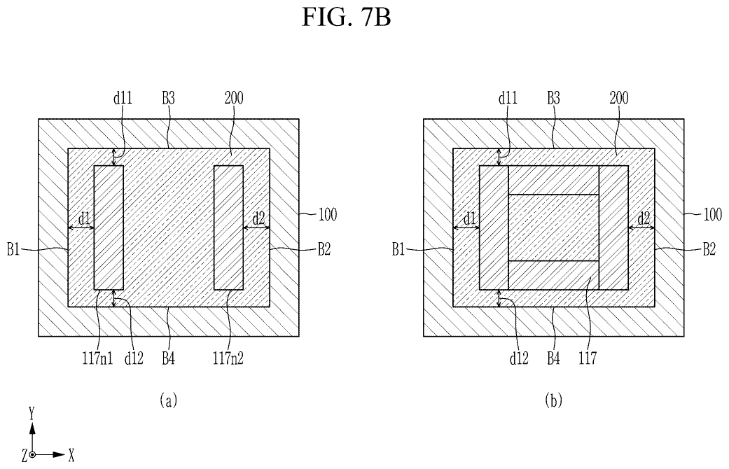

FIG. 7A schematically illustrates a semiconductor package manufacturing device according to some implementations, and FIG. 7B is a top view of a semiconductor package (e.g., the package of FIG. 7A) along, or from a perspective indicated by, line A-A′ of FIG. 7A. For example, a manufacturing device 700 may correspond to the manufacturing device 10 of FIG. 1, and some components of the manufacturing device 10 in FIG. 7A are omitted.

Referring to FIG. 7A, the manufacturing device 700 may perform a reflow process to electrically and mechanically couple a semiconductor chip 200 to the substrate 100. For example, the semiconductor chip 200 may be mounted on the substrate 100 in a flip-chip manner. The semiconductor chip 200 may include a semiconductor substrate 201 and a chip pad 202. The semiconductor substrate 201 may include a first surface 211 and a second surface 212 opposite the first surface 211 in the first direction (Z). The semiconductor substrate 201 may be formed from a semiconductor wafer. The semiconductor substrate 201 may include, for example, silicon (Si). The semiconductor substrate 201 may include a semiconductor element such as germanium (Ge), or a compound semiconductor such as silicon carbide (SiC), gallium arsenide (GaAs), indium arsenide (InAs), and indium phosphide (InP). The semiconductor substrate 201 may include a conductive region, for example, a well doped with impurities, or a structure doped with impurities. The semiconductor substrate 201 may include a semiconductor device layer including individual devices. The individual devices may include, for example, transistors. The individual devices may include microelectronic devices, such as metal-oxide-semiconductor field-effect transistors (MOSFET), system large-scale integration (LSI), image sensors such as CMOS imaging sensors (CIS), micro-electro-mechanical systems (MEMS), active devices, passive devices, etc. The chip pad 202 is formed on the second surface 212 of the semiconductor chip 200 and may be electrically connected to individual devices of the semiconductor device layer.

In some implementations, the semiconductor chip 200 may be a memory chip. The memory chip may be a volatile memory semiconductor device such as dynamic random-access memory (DRAM) and static random-access memory (SRAM), or a non-volatile memory semiconductor device such as phase-change random-access memory (PRAM), magnetoresistive random-access memory (MRAM), ferroelectric random-access memory (FeRAM), and resistive random-access memory (RRAM). In some implementations, the semiconductor chip 200 may be a logic chip. The logic chip may be a central processing unit (CPU) chip, a graphics processing unit (GPU) chip, an application processor (AP) chip, or an application-specific integrated circuit (ASIC) chip. However, the logic chip and the semiconductor chip 200 are not limited thereto.

In some implementations, the semiconductor chip 200 may be electrically and physically connected to the substrate 100 through a solder 220. The solder 220 may be attached to chip pads 202 of the semiconductor chip 200 and the upper connection pads 131 of the substrate 100. In some implementations, the manufacturing device 700 may perform reflow on the solder 220 disposed between the substrate 100 and the semiconductor chip 200. As a result, the semiconductor chip 200 may be bonded to the substrate 100, and a semiconductor package 300 may be manufactured. However, although it is stated here that the semiconductor chip 200 is connected to the substrate 100 via the solder 220, the connection is not limited thereto, and the semiconductor chip 200 may be electrically and physically connected to the substrate 100 via micro bumps or metal pillars (e.g., copper pillars).

In some implementations, a portion of the second surface 212 of the semiconductor chip 200 may contact the first structures 117n1 and 117n2 disposed on the first passivation layer 113 of the substrate 100. According to some implementations, the first structures 117n1 and 117n2 may be disposed below the semiconductor chip 200 on the first passivation layer 113 of the substrate 100. Since the position and size of the semiconductor chip 200 to be bonded on the substrate 100 are determined in advance, the position of the first structures 117n1 and 117n2 on the substrate 100 may be determined based on the position and size of the semiconductor chip 200 to be bonded on the substrate 100. For example, the first structures 117n1 and 117n2 on the substrate 100 may be disposed within predetermined lengths d1 and d2 from a first sidewall B1 and a second sidewall B2 of the semiconductor chip 200.

Referring to FIG. 7B, the first structures 117n1 and 117n2 between the semiconductor chip 200 and the substrate 100 spaced apart from each other in the third direction (Z) on the substrate 100 may be formed in various shapes. As shown in (a) of FIG. 7B, the first structures 117n1 and 117n2 on the substrate 100 may be disposed within predetermined lengths d1 and d2 from the first sidewall B1 and the second sidewall B2 of the semiconductor chip 200 in the first direction (X) and may extend in the second direction (Y). The first structures 117n1 and 117n2 on the substrate 100 may be disposed within predetermined lengths d3 and d4 in the second direction (Y) from a third sidewall B3 and a fourth sidewall B4 of the semiconductor chip 200. The predetermined lengths d1, d2, d3, and d4 may be equal or different. As another example, as shown in (b) of FIG. 7B, a structure 117 may form a square-ring shape by extending in the first direction (X) and the second direction (Y) on the substrate 100. However, the shape of the structure formed on the substrate 100 is not limited thereto. Meanwhile, FIG. 7B illustrates the structures 117n1, 117n2, and 117 for convenience of description, and the structures 117n1, 117n2, and 117 are formed between the semiconductor chip 200 and the substrate 100 spaced apart from each other in the third direction (Z) on the substrate 100.

Referring to FIG. 7A, in some implementations, when a heater of the manufacturing device 700 heats the solder 220 to a predetermined temperature (e.g., 217°C., which may be the boiling point of the solder 220), a temperature sensor (not shown) in the manufacturing device 700 may detect this. When the solder 220 reaches a predetermined temperature (e.g., 217° C., which may be the boiling point of the solder 220), a compressor 720 may apply the plurality of forces F to the first surface 211 of the semiconductor chip 200. In some implementations, when the compressor 720 applies the forces F to the semiconductor chip 200, the gap between the semiconductor chip 200 and the substrate 100 may be kept constant by the first structures 117n1 and 117n2. For example, when the compressor 720 applies the forces F to the semiconductor chip 200, the first structures 117n1 and 117n2 support the semiconductor chip 200 on the substrate 100, so that a certain gap may be formed between the semiconductor chip 200 and the substrate 100. Additionally, warpage of the semiconductor chip 200 may be prevented or reduced. Here, the gap between the semiconductor chip 200 and the substrate 100 may be substantially equal to the length h1 (e.g., height) of the first structures 117n1 and 117n2 in the first direction (Z). Since the gap between the semiconductor chip 200 and the substrate 100 is formed to a predetermined length by the reflow process, there is an advantage in that a non-wet defect in which the solder 220 is not connected to the upper connection pad 131 may be prevented.

The structures 117n1, 117n2 can be the structures 27 shown in FIG. 1, and the substrate 100 can be the substrate 21 shown in FIG. 1. The semiconductor chip 200 can be a chip 23-1, 23-3, or 23-5 shown in FIG. 1. The compressor 720 can be the compressor 17 shown in FIG. 1.

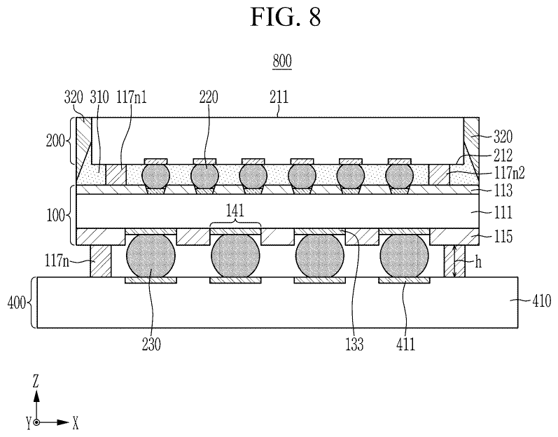

Referring to FIG. 8, in some implementations, after the semiconductor chip 200 is bonded to the substrate 100 on which the semiconductor chip 200 is mounted, an underfill material 310 is formed between the semiconductor chip 200 and the substrate 100. The underfill material 310 may also fill the gap between the semiconductor chip 200 and another adjacent semiconductor chip (not shown) on the substrate 100. The underfill material 310 includes, for example, but is not limited to, polymers and other non-conductive materials. The underfill material 310 may be distributed in the gap between the semiconductor chip 200 and the substrate 100. For example, the underfill material 310 may be distributed between the solder 220 between the semiconductor chip 200 and the substrate 100 and/or in the gap between the solder 220 and the first structures 117n1 and 117n2. After the underfill material 310 is distributed in a flowable form, a curing process may be performed to cure the underfill material 310. As shown in FIG. 8, in some implementations, as the underfill material 310 extends from the second surface 212 of the semiconductor chip 200 toward the substrate 100, the width (e.g., length in the third direction (X)) of the underfill material 310 may increase due to gravity.

According to some implementations, since the reflow process is performed while the substrate 100 and the semiconductor chip 200 are supported by the first structures 117n1 and 117n2, the gap between the semiconductor chip 200 and the substrate 100 may be formed to be constant, and the underfill material 310 may be uniformly distributed between the semiconductor chip 200 and the substrate 100. Accordingly, it is possible to prevent or reduce defects such as underfilling or overflow of the underfill material 310.

After the underfill material 310 is formed, a molding material 320 is formed around the semiconductor chip 200, and the semiconductor chip 200 may be embedded in the molding material 320. The molding material 320 may include, for example, an epoxy, an organic polymer, a polymer with or without added silica-based or glass fillers, or other materials. After the molding material 320 is distributed in a flowable shape, a curing process may be performed to cure the molding material 320. To remove excess portions of the molding material 320 from the first surface 211 of the semiconductor chip 200, a planarization process such as a chemical mechanical polishing (CMP) process or a mechanical grinding process may be performed.

In some implementations, lower openings 141 may be formed by an exposure and development process on the second passivation layer 115 of the substrate 100 to expose the lower connection pads 133.

In some implementations, a semiconductor package 800 may further include a lower substrate 400 disposed below the substrate 100. The lower substrate 400 may be, for example, a printed circuit board (PCB). The lower substrate 400 may include an insulating layer 410 and connection pads 411 disposed on the insulating layer 410. The connection pads 411 of the lower substrate 400 may be connected to a solder 230. The lower substrate 400 and the substrate 100 may be electrically and physically connected through the solder 230.

In some implementations, the semiconductor package 800 may further include a structure 117n extending in, or protruding in, the first direction (Z) on the lower substrate 400, and the manufacturing device (700 of FIG. 7) may reflow the solder 230 disposed on the lower connection pads 133. This enables the solder 230 to be electrically connected to the lower connection pad 133 and the connection pad 411. The gap between the lower substrate 400 and the substrate 100 in the first direction (Z) may be substantially equal to a length h (or height) of the structure 117n in the first direction (Z). The method of forming the semiconductor package 800 is the same as or similar to the method of forming the semiconductor package according to FIGS. 2 to 7, so a detailed description thereof is omitted here.

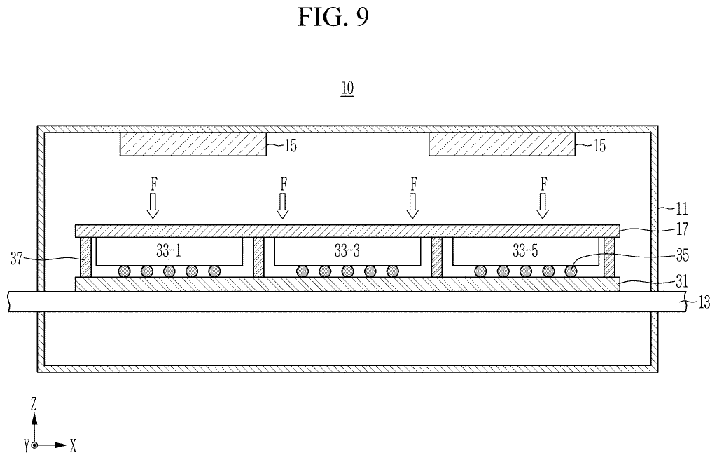

FIG. 9 schematically illustrates a semiconductor package manufacturing device according to some implementations of the present disclosure. The manufacturing device 10 may be a reflow device configured to perform a reflow process on a solder 35 between a substrate 31 positioned on the stage 13 and a plurality of semiconductor chips 33-1, 33-3, and 33-5. Since the configuration of the manufacturing device 10 of FIG. 9 is identical or similar to the configuration of the manufacturing device 10 of FIG. 1, a specific description of the manufacturing device 10 is omitted here.

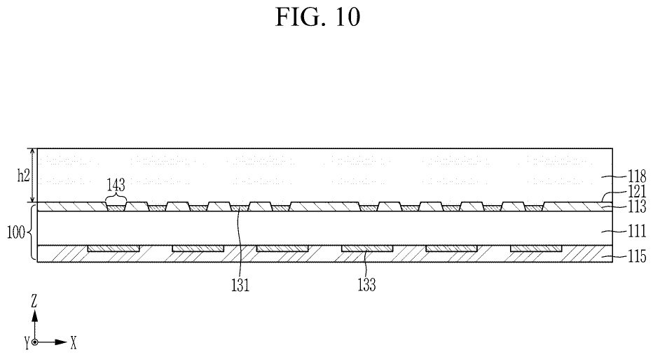

In some implementations, a structure 37 may be positioned between the substrate 31 and the plurality of semiconductor chips 33-1, 33-3, and 33-5. During the manufacturing process of a semiconductor package, the structure 37 positioned on the substrate 31 may be formed. The structure 37 may include, for example, a solder resist. According to some implementations, the structure 37 may contact a portion of the substrate 31 and a portion of the compressor 17. The structure 37 may be positioned between the plurality of semiconductor chips 33-1, 33-3, and 33-5 positioned on the substrate 31. The structure 37 may be spaced apart from the plurality of semiconductor chips 33-1, 33-3, and 33-5 positioned on the substrate 31 by a predetermined distance. A specific description of the method for forming the structure 37 will be described later with reference to FIGS. 10 to 13.

In some implementations, the compressor 17 may apply the plurality of forces F to the plurality of semiconductor chips 33-1, 33-3, and 33-5. For example, when the heater 15 heats the solder 35 to a predetermined temperature (e.g., 217° C., which may be the boiling point of the solder 35), the compressor 17 may apply the plurality of forces F to the plurality of semiconductor chips 33-1, 33-3, and 33-5 to prevent warpage of the plurality of semiconductor chips 33-1, 33-3, and 33-5. At this time, since the structure 37 supports the compressor 17 on the substrate 31, the gap between the plurality of semiconductor chips 33-1, 33-3, and 33-5 and the substrate 31 may be formed to be constant with a predetermined length or height.

FIGS. 10 to 13 are cross-sectional views of intermediate steps or stages in the formation of an example of a semiconductor package. Here, descriptions identical or similar to those in FIGS. 2 to 7 are omitted. Meanwhile, for convenience of description, only some semiconductor chips (e.g., 33-1 and 33-3) among the plurality of semiconductor chips 33-1, 33-3, and 33-5 (or more) positioned on the substrate 31 of FIG. 9 are illustrated below.

Referring to FIG. 10, in some implementations, the substrate 100 may include the base layer 111, the first passivation layer 113, and the second passivation layer 115, and the first passivation layer 113 may include the upper openings 143 for exposing the upper connection pads 131.

In some implementations, a third material layer 118 may be formed on the first passivation layer 113. The third material layer 118 may include, for example, a solder resist. The third material layer 118 may cover the upper surface 121 of the substrate 100. The third material layer 118 may be provided from, formed from, or composed of DFSR or a liquid solder resist material. In some implementations, the third material layer 118 may extend in, or protrude in, the first direction (Z) on the first passivation layer 113 and the upper connection pads 131 within the upper openings 143. For example, the third material layer 118 may extend from the first passivation layer 113 in the first direction (Z) by a second length h2. Here, the second length h2 may be a predetermined length. According to some implementations, the second length h2 of the third material layer 118 is the sum of the gap between the substrate 100 and the semiconductor chip (33 of FIG. 9) and the length (or thickness) of the semiconductor chip 33 in the third direction (Z), so that the separation distance between the substrate 100 and the semiconductor chip 33 may be determined by the second length h2 of the third material layer 118.

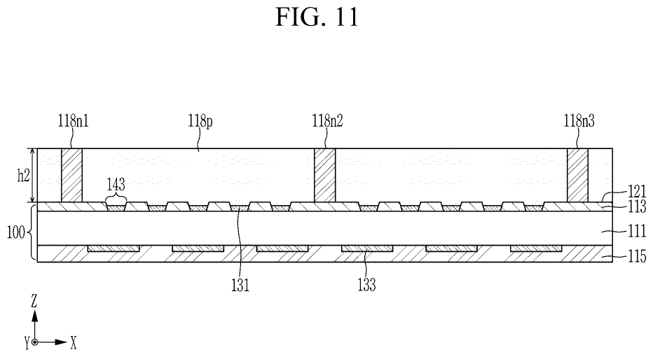

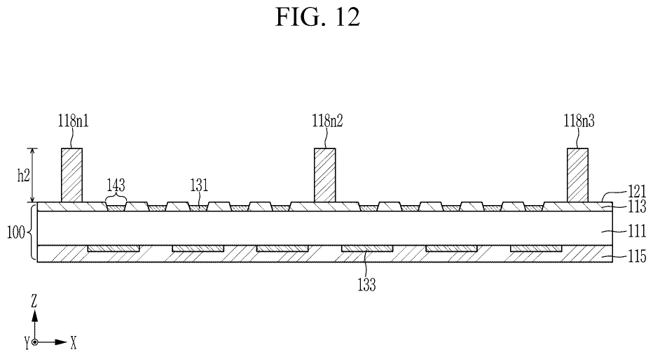

Referring to FIG. 11, in some implementations, an exposure process may be performed on the third material layer 118. As a result of performing the exposure process on the third material layer 118, the third material layer 118 may include an exposed region 118p that has been exposed and unexposed regions 118n1, 118n2, and 118n3 that have not been exposed. Then, a development process for the third material layer 118 may be performed. Referring to FIG. 12, as a result of performing the development process for the third material layer 118, the exposed region 118p of the third material layer 118 may be removed, and the unexposed regions 118n1, 118n2, and 118n3 may remain. Hereinafter, the unexposed regions may be referred to as the second structures 118n1, 118n2, and 118n3.

In some implementations, the second structures 118n1, 118n2, and 118n3 may extend in the second direction (Y) on the first passivation layer 113. Although the second structures 118n1, 118n2, and 118n3 are shown here as extending in the second direction (Y), their extension is not limited thereto. For example, the second structures 118n1, 118n2, and 118n3 may extend in the first direction (X) on the first passivation layer 113, or may extend in the first direction (X) and the second direction (Y) on the first passivation layer 113, thereby having, for example, a square-ring shape.

In some implementations, the second structures 118n1, 118n2, and 118n3 may be formed of an insulating material. For example, the second structures 118n1, 118n2, and 118n3 may include solder resist, epoxy resin, and/or polyimide. In some implementations, the second structures 118n1, 118n2, and 118n3 may be formed of the same material as the first passivation layer 113 of the substrate 100. For example, the lower portion of the second structures 118n1, 118n2, and 118n3 may be in contact with the first passivation layer 113 and may be formed of the same material (e.g., solder resist) as the first passivation layer 113.

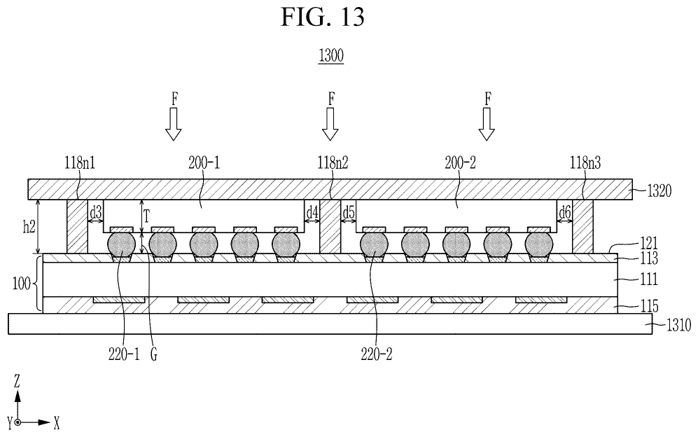

FIG. 13 schematically illustrates a semiconductor package manufacturing device according to some implementations. For example, a manufacturing device 1300 may correspond to the manufacturing device 10 of FIG. 9, and some components of the manufacturing device 10 are omitted in FIG. 13.

Referring to FIG. 13, the manufacturing device 1300 may perform a reflow process to electrically and mechanically couple a first semiconductor chip 200-1 and a second semiconductor chip 200-2 to the substrate 100. The first semiconductor chip 200-1 and the second semiconductor chip 200-2 may be mounted on the substrate 100 in a flip-chip manner. The first semiconductor chip 200-1 and the second semiconductor chip 200-2 may be spaced apart from each other on the substrate 100.

In some implementations, the first semiconductor chip 200-1 and the second semiconductor chip 200-2 may be electrically and physically connected to the substrate 100 through solders 220-1 and 200-2. In some implementations, the manufacturing device 1300 performs reflow on the solders 220-1 and 220-2 positioned between the substrate 100 of a stage 1310 and the semiconductor chips 200-1 and 200-2, thereby bonding the semiconductor chips 200-1 and 200-2 to the substrate 100.

In some implementations, the second structures 118n1, 118n2, and 118n3 on the substrate 100 may be positioned between the semiconductor chips 200-1 and 200-2. For example, a structure 118n2 may be positioned between the first semiconductor chip 200-1 and the second semiconductor chip 200-2. The second structures 118n1, 118n2, and 118n3 on the substrate 100 may be positioned between the semiconductor chips 200-1 and 200-2 in the first direction (X) and/or the second direction (Y). For example, the structure 118n2 may be positioned between the first semiconductor chip 200-1 and the second semiconductor chip 200-2 in the first direction (X).

In some implementations, the second structures 118n1, 118n2, and 118n3 on the substrate 100 may be spaced apart from the semiconductor chips 200-1 and 200-2 by a predetermined distance. For example, among the second structures 118n1, 118n2, and 118n3, the structure 118n1 may be spaced apart from the first semiconductor chip 200-1 by a third distance d3; among the second structures 118n1, 118n2, and 118n3, the structure 118n2 may be spaced apart from the first semiconductor chip 200-1 and the second semiconductor chip 200-2 by a fourth distance d4 and a fifth distance d5; and among the second structures 118n1, 118n2, and 118n3, the structure 118n3 may be spaced apart from the second semiconductor chip 200-2 by a sixth distance d6. The second structures 118n1, 118n2, and 118n3 on the substrate 100 may be spaced apart from the semiconductor chips 200-1 and 200-2 by a predetermined distance in the first direction (X) and/or the second direction (Y). For example, the first semiconductor chip 200-1 may be positioned between the structure 118n1 and the structure 118n2. The first semiconductor chip 200-1 may be positioned between the structure 118n1 and the structure 118n2 in the first direction (X). However, the positioning is not limited thereto. In some implementations, since the positions and sizes of the semiconductor chips 200-1 and 200-2 to be bonded on the substrate 100 are determined in advance, the positions of the second structures 118n1, 118n2, and 118n3 on the substrate 100 may be determined based on the positions and sizes of the semiconductor chips 200-1 and 200-2 to be bonded on the substrate 100. Here, each distance d3, d4, d5, and d6 may be equal to or different from each other. In addition, although two semiconductor chips 200-1 and 200-2 are shown here as being bonded on the substrate 100, the number of semiconductor chips is not limited thereto, and the number of second structures may also vary depending on the number of semiconductor chips.

In some implementations, when the heater of the manufacturing device 1300 heats the solders 220-1 and 220-2 to a predetermined temperature (e.g., 217° C., which may be the boiling point of the solders 220-1 and 220-2), a temperature sensor in the manufacturing device 1300 may detect this. When the solders 220-1 and 220-2 reach a predetermined temperature (e.g., 217° C., which is the boiling point of the solders 220-1 and 220-2), a compressor 1320 may apply the plurality of forces F to the semiconductor chips 200-1 and 200-2. In some implementations, when the compressor 1320 applies the force F to the semiconductor chips 200-1 and 200-2, the gap between the semiconductor chips 200-1 and 200-2 and the substrate 100 may be kept constant by the second structures 118n1, 118n2, and 118n3. For example, when the compressor 1320 applies the force F to the semiconductor chip 200, the second structures 118n1, 118n2, and 118n3 support the compressor 1320, so that a certain gap may be formed between the semiconductor chips 200-1 and 200-2 and the substrate 100. The length h2 of the second structures 118n1, 118n2, and 118n3 in the first direction (Z) may be substantially equal to the sum of a gap G between the semiconductor chips 200-1 and 200-2 and the substrate 100 in the first direction (Z) and a height T of the semiconductor chips 200-1 and 200-2 in the first direction (Z). Accordingly, warpage of the semiconductor chips 200-1 and 200-2 is prevented or reduced, and the gap between the semiconductor chips 200-1 and 200-2 and the substrate 100 may be formed to a predetermined length.

The structures 118n1, 118n2, 118n3 can be the structures 37 shown in FIG. 9, and the substrate 100 can be the substrate 31 shown in FIG. 9. The semiconductor chips 200-1, 200-2 can be chips 33-1, 33-3, 33-5 shown in FIG. 9. The compressor 1320 can be compressor 17 shown in FIG. 9.

Then, an underfill process for forming an underfill material between the semiconductor chips 200-1 and 200-2 and the substrate 100 and a molding process for embedding the semiconductor chips 200-1 and 200-2 may be performed. Since the processes are identical or similar to the process described in FIG. 8, a detailed description thereof is omitted here.

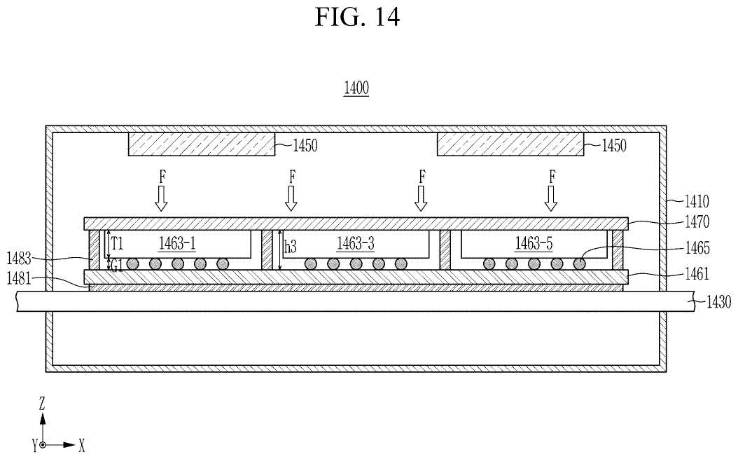

FIG. 14 schematically illustrates a semiconductor package manufacturing device according to some implementations.

In some implementations, a manufacturing device 1400 may include a process chamber 1410 and a stage 1430. The process chamber 1410 may form an internal space for performing a manufacturing process for a package structure including a substrate 1461 and semiconductor chips 1463-1, 1463-3, and 1463-5. In some implementations, the manufacturing device 1400 may include a lower jig 1481 that supports the substrate 1461 on the stage 1430 and an upper jig 1483 that presses an upper surface of the substrate 1461. In some implementations, the stage 1430 may include a conveyor belt configured to transport the substrate 1461 and the semiconductor chips 1463-1, 1463-3, and 1463-5 in one direction.

In some implementations, the lower jig 1481 may be formed into a plate shape having a predetermined thickness. For example, the lower jig 1481 may be formed of a heat-resistant and corrosion-resistant material, such as stainless steel. The lower jig 1481 may include a plurality of holes penetrating the lower jig 1481. For example, during the reflow process, the substrate 1461 and the semiconductor chips 1463-1, 1463-3, and 1463-5 may be supplied with heated vapor through the through holes of the lower jig 1481. The lower jig 1481 may seat and support the substrate 1461 on the upper surface thereof.

In some implementations, the upper jig 1483 may contact the upper surface of the substrate 1461. The upper jig 1483 may be formed of the same or a similar material as the lower jig 1481. For example, the upper jig 1483 may be formed of a heat-resistant and corrosion-resistant material, such as stainless steel. The upper jig 1483 may pressurize the substrate 1461 between the semiconductor chips 1463-1, 1463-3, and 1463-5 positioned on the substrate 1461. A length h3 of the upper jig 1483 in the first direction (Z) may be substantially equal to the sum of a gap G1 between the semiconductor chips 1463-1, 1463-3, and 1463-5 and the substrate 1461 in the first direction (Z) and a height T1 of the semiconductor chips 1463-1, 1463-3, and 1463-5 in the first direction (Z).

In some implementations, the manufacturing device 1400 may be a reflow device configured to perform a reflow process on a solder 1465 positioned between the substrate 1461 and the semiconductor chips 1463-1, 1463-3, and 1463-5. The manufacturing device 1400 may include a heater 1450 in the process chamber 1410. The heater 1450 may include a heat source for heating the solder 1465 to a predetermined temperature.

In some implementations, the manufacturing device 1400 may include a compressor 1470. For example, when the heater 1450 heats the solder 1465 to a predetermined temperature (e.g., 217° C., which may be the boiling point of the solder 1465), the compressor 1470 may apply the plurality of forces F to the semiconductor chips 1463-1, 1463-3, and 1463-5 to prevent warpage of the semiconductor chips 1463-1, 1463-3, and 1463-5. At this time, the upper jig 1483 pressurizes the substrate 1461 between the substrate 1461 and the compressor 1470 and supports the compressor 1470, so that the gap between the semiconductor chips 1463-1, 1463-3, and 1463-5 and the substrate 1461 may be formed to a predetermined length (or height). Therefore, there is an advantage in that warpage of the semiconductor chips 1463-1, 1463-3, and 1463-5 may be prevented or reduced, and non-wet defects for the solder 1465 may be prevented or reduced. After the reflow process, the upper jig 1483 may be separated from the substrate 1461.

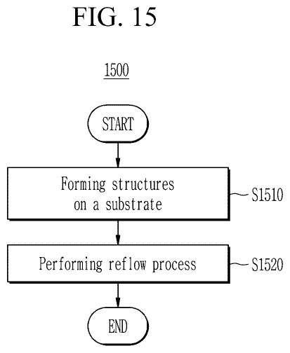

FIGS. 15 to 17 are flowcharts of semiconductor package manufacturing methods according to some implementations of the present disclosure. The methods illustrated in FIGS. 15 to 17 may be modified without departing from the scope of this disclosure. For example, various steps may be added, removed, replaced, and/or repeated in the methods illustrated in FIGS. 15 to 17.

Referring to FIG. 15, a semiconductor package manufacturing method 1500 may include a step of forming structures on a substrate (S1510).

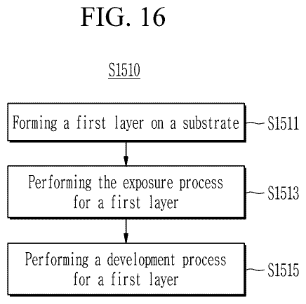

Referring to FIG. 16, the step of forming structures on a substrate (S1510) may include a step of forming a first layer on a substrate (S1511). As described above with reference to FIGS. 4 and 10, the first layer on the substrate may extend in, or protrude in the first direction (Z), and the separation distance between the substrate and the semiconductor chip may be determined by the length of the first layer in the first direction (X). The first layer may include, but is not limited to, a solder resist. The step of forming structures on a substrate (S1510) may include a step of performing an exposure process for a first layer (S1513). As described above with reference to FIGS. 5 and 11, as a result of performing the exposure process for the first layer, the first layer may include an exposed region and an unexposed region. The step of forming structures on a substrate (S1510) may include a step of performing a development process for a first layer (S1515). As described above with reference to FIGS. 6 and 12, the exposed region of the first layer may be removed by the development process. Therefore, the unexposed region of the first layer may be formed into a structure on the substrate.

Referring to FIG. 15, the semiconductor package manufacturing method 1500 may include a step of performing a reflow process (S1520). The step of performing a reflow process (S1520) may be performed in a manufacturing device (e.g., 10 of FIG. 1 or FIG. 9).

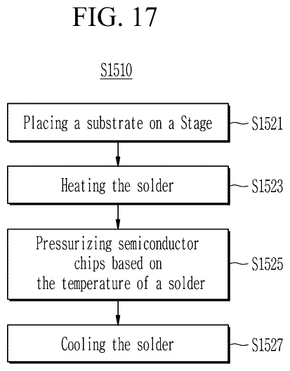

Referring to FIG. 17, the step of performing a reflow process (S1520) may include a step of placing a substrate on a stage (S1521). Then, a step of heating a solder (S1523) may be included to bond the semiconductor chip disposed on the substrate and the substrate. When the solder reaches a predetermined temperature (e.g., 217° C., which may be the boiling point of the solder) by step (S1523), a manufacturing device may pressurize the semiconductor chip (S1525). For example, when a semiconductor chip is disposed in a first direction with respect to the substrate, the manufacturing device may pressurize the semiconductor chip (or apply a force or pressure to the semiconductor chip) in a direction opposite to the first direction based on the temperature of the solder, e.g., in response to sensing that the solder has reached the predetermined temperature. By the pressurizing operation of the manufacturing device, warpage of the semiconductor chip may be prevented or reduced. In addition, warpage of the semiconductor chip is prevented or reduced by the structure formed in the step (S1510), and the gap between the semiconductor chip and the substrate may be formed to be constant. Then, a step (S1527) of cooling the heated solder may be performed.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While various examples are described in detail above, the scope of the present disclosure is not limited thereto, and it will be apparent to those of ordinary skill in the art that modifications and variations may be made without departing from the scope of the present disclosure. In addition, the aforementioned implementations may be implemented with some elements removed, and each example may be implemented in combination with each other.

What is claimed is:

1. A semiconductor package, comprising:
a substrate including a first layer;
a plurality of structures, wherein the plurality of structures protrude from the first layer in a first direction by a first length and include a same material as the first layer; and
a first semiconductor chip bonded to the substrate,
wherein (i) a first surface of the first semiconductor chip and (ii) the substrate are separated from one another in the first direction by a separation distance, and the separation distance is determined based on the first length.

2. The semiconductor package of claim 1, wherein a first structure of the plurality of structures extends from the first layer to the first surface of the first semiconductor chip, and
wherein the first length is substantially equal to the separation distance.

3. The semiconductor package of claim 2, wherein the first surface comprises a plurality of regions, and wherein each region of the plurality of regions is in contact with a corresponding structure of the plurality of structures.

4. The semiconductor package of claim 2, wherein the plurality of structures extend in a second direction perpendicular to the first direction.

5. The semiconductor package of claim 2, further comprising:
a solder that contacts the first surface and electrically connects the substrate and the first semiconductor chip;
an underfill material around the solder and the plurality of structures between the first semiconductor chip and the substrate; and
a molding material around the first semiconductor chip.

6. The semiconductor package of claim 1, wherein the first length is equal to the sum of the separation distance and the thickness of the first semiconductor chip in the first direction.

7. The semiconductor package of claim 6, further comprising:
a second semiconductor chip bonded to the substrate and spaced apart from the first semiconductor chip,
wherein a first structure of the plurality of structures is disposed between the first semiconductor chip and the second semiconductor chip.

8. The semiconductor package of claim 7, wherein the first semiconductor chip is disposed between the first structure and a second structure of the plurality of structures.

9. The semiconductor package of claim 1, wherein the same material of the plurality of structures and the first layer comprises a solder resist.

10. A semiconductor package manufacturing method, comprising:
forming a structure that protrudes from a substrate in a first direction;
heating a solder that electrically connects a semiconductor chip and the substrate, wherein the semiconductor chip is spaced apart from the substrate in the first direction; and
applying a pressure to the semiconductor chip in a direction opposite to the first direction,
wherein a first surface of the semiconductor chip contacts the structure, wherein the structure includes a solder resist, and wherein the first surface faces the substrate.

11. The semiconductor package manufacturing method of claim 10, wherein forming the structure comprises:
forming, on the substrate, a first layer; and
forming a first region of the first layer as the structure.

12. The semiconductor package manufacturing method of claim 11, wherein forming the first region as the structure comprises:
performing an exposure process on the first layer to define the first region and a second region that excludes the first region; and
performing a development process on the first layer to remove the second region.

13. The semiconductor package manufacturing method of claim 11, wherein the first layer has a first thickness in the first direction, and wherein the first thickness is substantially equal to a gap between the semiconductor chip and the substrate.

14. The semiconductor package manufacturing method of claim 13, wherein the first thickness is substantially equal to a length of the structure in the first direction.

15. The semiconductor package manufacturing method of claim 10, wherein applying the pressure to the semiconductor chip in the direction opposite to the first direction comprises:
determining that a temperature of the solder has reached a predetermined temperature; and
based on determining that the temperature of the solder has reached the predetermined temperature, applying the pressure to a second surface of the semiconductor chip, wherein the second surface is opposite to the first surface.

16. The semiconductor package manufacturing method of claim 15, wherein the predetermined temperature is a boiling point of the solder.

17. The semiconductor package manufacturing method of claim 15, further comprising cooling the solder.

18. The semiconductor package manufacturing method of claim 10, further comprising:
forming an underfill material around the solder and the structure, wherein the underfill material is between the semiconductor chip and the substrate; and
forming a molding material around the semiconductor chip.

19. A semiconductor package manufacturing device, comprising:
a first jig disposed on a stage and in contact with a first surface of a substrate;
a second jig in contact with a second surface of the substrate, wherein the second surface is opposite to the first surface;
a heater configured to heat a solder that electrically connects the substrate with a semiconductor chip bonded to the substrate, wherein the substrate and the semiconductor chip are spaced apart in a first direction; and
a compressor configured to pressurize a fourth surface of the semiconductor chip, wherein the fourth surface is opposite to a third surface of the semiconductor chip, and wherein the third surface faces the substrate,
wherein a length of the second jig in the first direction is equal to a sum of a gap between the substrate and the semiconductor chip in the first direction and a thickness of the semiconductor chip in the first direction.

20. The semiconductor package manufacturing device of claim 19, wherein the second jig is in contact with the compressor.
